(19) United States
(12) Patent Application Publication
(10) Pub. No.: US 2015/0372012 A1
(43) Pub. Date: Dec. 24, 2015

(54) ARRAY SUBSTRATE, METHOD OF PRODUCING ARRAY SUBSTRATE, AND DISPLAY PANEL

(71) Applicants: Boe Technology Group Co., Ltd., Beijing (CN); Beijing Boe Display Technology Co., Ltd., Beijing (CN)

(72) Inventors: Yusheng Xi, Beijing (CN); Haichen Hu, Beijing (CN); Ming Tian, Beijing (CN)

(21) Appl. No.: 14/500,402

(22) Filed: Sep. 29, 2014

(30) Foreign Application Priority Data
Jun. 19, 2014 (CN) 201410276679.7

(51) Int. Cl. H01L 27/12; H01L 21/768; H01L 29/40; H01L 29/786

(52) U.S. Cl. CPC H01L 27/124; H01L 27/1248; H01L 27/1259; H01L 29/7869; H01L 21/76802; H01L 29/401

(57) ABSTRACT

An array substrate, a method of producing the array substrate, and a display panel incorporating the array substrate are disclosed. The array substrate includes a substrate, a gate line, a gate insulating layer, and a data line. The gate line and/or the data line is provided with a via hole at a position corresponding to a spacer. In this manner, a problem of a display panel having gaps of different sizes after assembly because of nonuniform thicknesses of the gate line and/or the data line can be avoided, which, in turn, prevents inhomogeneous color in the display.

### RELATED APPLICATIONS

The present application claims the benefit of Chinese Patent Application No. 201410276679.7, filed Jun. 19, 2014, the entire disclosure of which is incorporated herein by reference.

### FIELD

The present invention relates to the field of display technology, and particularly to an array substrate, a method of producing the array substrate, and a display panel incorporating the array substrate.

### BACKGROUND

During the production of a conventional Thin Film Transistor Liquid Crystal Display (TFT-LCD) panel, gate lines and data lines are usually formed using a sputtering device. Inherent deficiencies in the structure of the sputtering device lead to the problem of nonuniform film thicknesses of the gate lines and the data lines formed by said sputtering device.

It is typically required to fouls a spacer between an array substrate and a color-film substrate during formation of the TFT-LCD panel. The spacer is made at a corresponding position in the gate line and/or the data line on the array substrate. Since the thicknesses of the gate line and the data line are nonuniform, and the spacer plays the role of supporting the whole substrate, gaps between the array substrate and the color-film substrate have different sizes after cell assembly of the two substrates, which gives rise to the problem of inhomogeneous color in the formed display so that said panel does not function properly. This leads to a waste of the production material and an increase in the product cost.

Accordingly, there is an unmet need to solve these problems associated with production of TFT-LCD panels.

### SUMMARY

An array substrate is provided in accordance with a first exemplary aspect of the present disclosure. The array substrate comprises a substrate, a gate line, a gate insulating layer, and a data line. Said gate line and/or said data line of said array substrate is provided with a via hole at a position corresponding to a spacer.

With the array substrate of the present disclosure, it is possible to avoid the problem of display panels that have gaps of different sizes after cell assembly because of nonuniform thicknesses of the gate line and/or the data line at a position on the array substrate corresponding to the spacer, thereby avoiding inhomogeneous color in the display and preventing increased production costs.

In an exemplary aspect of the present disclosure, said gate line and said gate insulating layer of said array substrate are both provided with a via hole at a position corresponding to said spacer.

In an exemplary aspect of the present disclosure, said passivation layer of said array substrate is provided with a via hole at a position corresponding to said spacer.

In an exemplary aspect of the present disclosure, the array substrate to which said spacer position corresponds comprises an active layer, a passivation layer, and an ITO pixel electrode layer.

In an exemplary aspect of the present disclosure, the array substrate to which said spacer position corresponds comprises a first ITO pixel electrode layer, an active layer, a passivation layer, and a second ITO pixel electrode layer.

A method of producing an array substrate is provided in accordance with a second exemplary aspect of the present disclosure. The method comprises forming a gate metal layer on a substrate; forming a via hole in said gate metal layer at a position corresponding to a spacer; forming a gate insulating layer on said gate metal layer; forming a source electrode, a drain electrode, and a data line on said gate insulating layer; and forming a via hole in said data line at the position corresponding to said spacer.

In an exemplary aspect of the present disclosure, a gate metal layer is formed on said substrate by forming a gate metal layer comprising a gate line and a gate on said substrate using a patterning process, and forming a via hole in said gate line at a position corresponding to said spacer.

In an exemplary aspect of the present disclosure, a gate metal layer is formed on said substrate by forming a gate metal layer comprising a gate line and a gate on said substrate using a patterning process; and, after forming a gate insulating layer on said gate metal layer, forming a via hole penetrating said gate line and said gate insulating layer at a position corresponding to said spacer.

In an exemplary aspect of the present disclosure, a source electrode, a drain electrode, and a data line are formed on said gate insulating layer by forming a source electrode, a drain electrode, and a data line on said gate insulating layer using a patterning process; and forming a via hole in said line data at a position corresponding to said spacer.

In an exemplary aspect of the present disclosure, said method further comprises forming a via hole in said gate insulating layer at a position corresponding to said spacer.

In an exemplary aspect of the present disclosure, said method further comprises forming a via hole in said passivation layer at a position corresponding to said spacer.

A display panel is provided in accordance with a third exemplary aspect of the present disclosure. The display panel comprises the array substrate described above.

With the array substrate, the method of producing the same, and the display panel incorporating the same, as provided in the respective examples of the present disclosure, by setting a via hole in the gate line and/or the data line on the array substrate at a position corresponding to the spacer, the gate line and/or the data line on the array substrate to which the spacer position corresponds are removed, thereby solving the problem in conventional display panels involving gaps that have different sizes after cell assembly of the display panels because of nonuniform thicknesses of the gate line and/or the data line on the array substrate to which the spacer corresponds. As a result, the display panels do not exhibit inhomogeneous color in their display.

### BRIEF DESCRIPTION OF THE DRAWINGS

Several technical aspects of the present disclosure will be described in more detail below with reference to the accompanying drawings in order for those skilled in the art to be able to carry out the present disclosure. The present disclosure may, however, be embodied in many different forms and should not be construed as limited to the exemplary embodiments set forth herein. In particular, the general inventive concepts are not intended to be limited by the various illustrative embodiments disclosed herein.

FIG. 1 is a structural diagram of an array substrate, according to an exemplary embodiment;

FIG. 2 is a structural diagram of another array substrate, according to an exemplary embodiment;

FIG. 3 is a structural diagram of yet another array substrate, according to an exemplary embodiment;

FIG. 4 is a flow diagram of a method of producing an array substrate, according to an exemplary embodiment;

FIG. 5 is a flow diagram of a method of producing another array substrate, according to an exemplary embodiment;

FIG. 6 is a flow diagram of a method of producing yet another array substrate, according to an exemplary embodiment;

FIG. 7 is a flow diagram of a method of producing another array substrate, according to an exemplary embodiment;

FIG. 8 is a flow diagram of a method of producing yet another array substrate, according to an exemplary embodiment; and

FIG. 9 is a flow diagram of a method of producing still another array substrate, according to an exemplary embodiment.

The reference numerals presented in the drawings are explained as follow: 1—substrate; 2—gate line; 3—gate insulating layer; 4—passivation layer; 5—active layer; 6—second ITO pixel electrode layer; and 7—first ITO pixel electrode layer.

### DETAILED DESCRIPTION

The present invention and associated general inventive concepts will be further described hereinafter in detail with reference to the accompanying drawings and various exemplary embodiments. One of ordinary skill in the art will appreciate that these exemplary embodiments only constitute some of the possible embodiments encompassed by the present invention and associated general inventive concepts. As such, the scope of the present disclosure is by no means limited to the exemplary embodiments set forth herein.

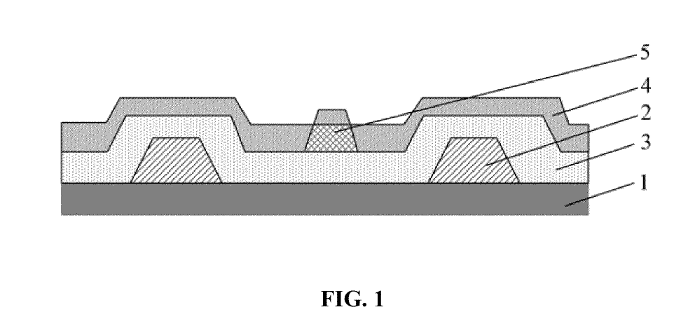

As shown in FIG. 1, an array substrate, according to an exemplary embodiment, comprises a substrate 1, a gate line 2, a gate insulating layer 3, and a data line (not shown), wherein a spacer is set at a position corresponding to the gate line 2, and wherein a via hole is provided at the position in the gate line 2 of the array substrate 1 which corresponds to the spacer. Likewise, when the spacer is set at a position corresponding to the data line, a via hole is provided at the position in the data line which corresponds to the spacer. If the spacer is set at a position corresponding to both the gate line 2 and the data line, a via hole is provided at both positions corresponding to the gate line 2 and the data line, respectively.

The “via hole,” as used and described herein, is also called a metalized hole and has the following function: in a double-sided panel and a multi-layer panel, in order to connect the printed wires between respective layers, it is required to drill or otherwise form a hole at the junction of the wires of respective layers in need of connection, i.e., a “via hole.” In terms of process, the cylindrical surface of the hole wall of the via hole can be plated with a layer of metal using, for example, a chemical deposition method for connecting copper foils of the respective layers which are required to be connected. Said via hole can be not only a through-hole via hole, but also an in-ground via hole. The so-called through-hole via hole refers to a via hole penetrating all copper-coated layers. The in-ground via hole only penetrates several middle copper-coated layers, as if they are buried by other copper-coated layers.

As shown in FIG. 1, when the spacer is set at a position corresponding to the gate line 2, the position in the gate line 2 of the array substrate which is corresponding to the spacer is provided with a via hole. The via hole at the corresponding position in said gate line 2 may be formed together with the gate line 2 by a patterning process using a mask plate having a certain shape during the formation of the gate line 2.

Alternatively, when the spacer is set at a position corresponding to the data line, the position in the data line of the array substrate, which is corresponding to the spacer, is provided with a via hole. The via hole at the corresponding position in said data line may be formed together with the data line by a patterning process using a mask plate that can form a via hole in the data line during the formation of the data line. Any suitable shape of the mask plate can be used, as long as the mask plate can form a data line and form a via hole in the data line at a position corresponding to the spacer.

Alternatively, the positions in the gate line 2 and the gate insulating layer 3 of the array substrate are both provided with a via hole (not shown). Said via holes penetrate the gate line 2 and the gate insulating layer 3.

In an exemplary embodiment, the via holes penetrating the gate line 2 and the gate insulating layer 3 may be, respectively, formed by a patterning process using a mask plate during the production of the gate line 2 and/or the gate insulating layer 3. The via holes penetrating the gate line 2 and the gate insulating layer 3 may also be formed by etching, composition, etc. during the formation of the gate insulating layer 3.

In an exemplary embodiment, as shown in FIG. 1, the array substrate further comprises a passivation layer 4 and an active layer 5, wherein the passivation layer 4 of the array substrate is provided with a via hole at a position corresponding to the spacer (not shown).

If the gate insulating layer 3 and the passivation layer 4 are formed by a sputtering process using a sputtering device during production thereof, due to the deficiencies possessed by the sputtering device, and if the array substrate where the spacer is located has the gate insulating layer 3 and the passivation layer 4, there will be the problem of inhomogeneous color in the display because gaps of different sizes after cell assembly will result from nonuniform thicknesses of the gate insulating layer 3 and the passivation layer 4. During formation, however, via holes are provided at the positions in the gate insulating layer 3 and the passivation layer 4 which correspond to the spacer. In this manner, the gate insulating 3 layer and the passivation layer 4 are not present at the positions in the array substrate, which correspond to the spacer. As a result, the problem of nonuniform film thicknesses at spacer locations is avoided, which effectively avoids the related problem of inhomogeneous color in the display.

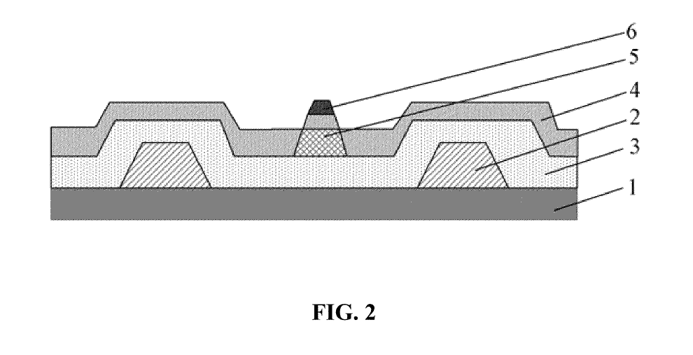

As shown in FIG. 2, the array substrate may further comprise a source electrode, a drain electrode, and an Indium Tin Oxide (ITO) pixel electrode layer 6, wherein the source electrode and the drain electrode are not shown in FIG. 2.

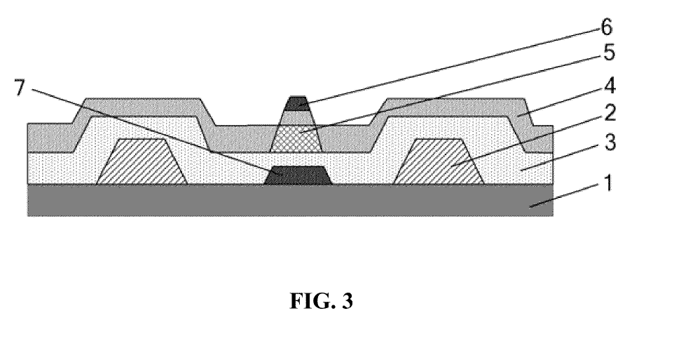

As shown in FIG. 3, the array substrate comprises two layers of ITO, i.e., a first ITO pixel electrode layer 7 and a second ITO pixel electrode layer 6, and the position in the gate line 2 which is corresponding to the spacer is provided with a via hole.

One of ordinary skill in the art will appreciate that FIG. 1 merely exemplifies one position of a via hole on the gate line 2, when the gate line 2 is provided with the via hole, but does not define that the via hole can only be set at said position. In practical application, the position of a via hole in the gate line 2 is determined by the position where the spacer is actually located.

In an exemplary embodiment, the array substrate to which the spacer position corresponds comprises an active layer 5, a passivation layer 4, and an ITO pixel electrode layer.

In an exemplary embodiment, the array substrate to which the spacer position corresponds comprises a first ITO pixel electrode layer 7, an active layer 5, a passivation layer 4, and a second ITO pixel electrode layer 6.

One of ordinary skill in the art will appreciate that the structures comprised by the array substrate to which the spacer position corresponds are merely exemplified herein. It is not intended that the array substrate can only comprise these structures. In practice, the structure of the array substrate to which the spacer position corresponds is detennined by the position of the spacer actually set.

In the respective exemplary embodiments, the sizes of the via holes at the positions in the gate line 2, the data line, the gate insulating layer 3, and the passivation layer 4 which correspond to the spacer are not uniquely limited here. The size of the via hole during actual production thereof can be set dependent on the size of the port of the spacer. The shape of the via hole is also not uniquely limited here. It can be a shape which is convenient to manufacture. It should be a shape through which the port of the spacer in the present examples can pass.

In the array substrate provided, according to an exemplary embodiment, by setting a via hole in the gate line 2 and/or the data line on the array substrate at a position corresponding to the spacer, the gate line 2 and/or the data line on the array substrate to which the spacer position corresponds are removed, such that there does not exist the problem that the gate line 2 and/or the data line on the array substrate to which the spacer position corresponds have nonuniform thicknesses, thereby solving the problem in conventional display panels of gaps having different sizes existing after cell assembly of display panels because of nonuniform thicknesses of the gate line and/or the data line on the array substrate to which the spacer corresponds. This, in turn, avoids the problem of inhomogeneous color in the display. Meanwhile, the qualification rate of the obtained displays can be greatly increased, which reduces waste of the production materials, significantly reduces production costs, and improves production efficiency.

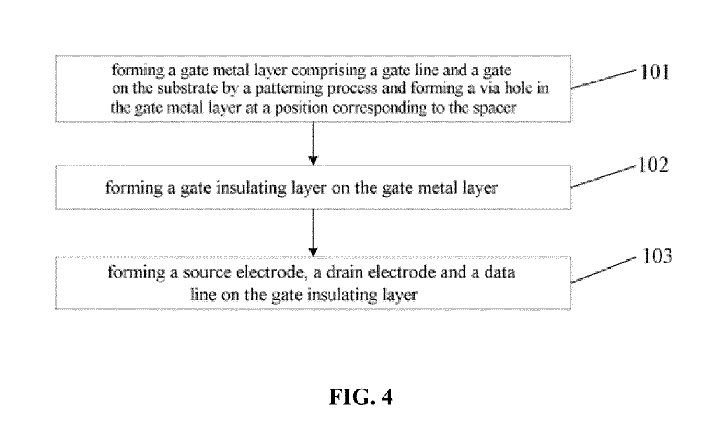

A method of producing an array substrate, according to an exemplary embodiment, is shown in FIG. 4. The method comprises the following steps:

Step 101 includes forming a gate metal layer comprising a gate line and a gate on a substrate by a patterning process, and forming a via hole in the gate metal layer at a position corresponding to a spacer. Specifically, a metal thin film layer having a thickness of from 1,000Å to 7,000Å is deposited on a substrate, such as glass or quartz substrate, using a magnetron sputtering method. Said metal thin film can employ any suitable material, such as molybdenum, aluminum, aluminum-nickel alloy, molybdenum-tungsten alloy, chromium, copper, etc., and can also employ a combined structure of the above thin film materials.

Thereafter, said metal thin film is treated with a mask plate by means of a patterning process such as exposure, development, etching, and stripping to form a gate metal layer over a certain region of the substrate.

Step 102 includes forming a gate insulating layer on the gate metal layer.

Specifically, a gate electrode insulating layer thin film having a thickness of from 1,000Å to 6,000Å is deposited on the substrate using a chemical vapor deposition method or a magnetron sputtering method. Said gate insulating layer thin film can employ any suitable material, such as nitrogen oxide, silicon oxide, silicon oxynitride, etc.

Step 103 includes forming a source electrode, a drain electrode, and a data line on the gate insulating layer. A metal thin film layer similar to the gate metal having a thickness of from 1,000Å . to 7,000Å is deposited on the substrate using a method similar to that used to produce the gate metal layer. Said metal thin film layer is treated by a patterning process to form a source electrode, a drain electrode, and a data line over a certain region.

In the method of producing an array substrate, according to this exemplary embodiment, by forming a via hole in the gate line on the array substrate at a position corresponding to the spacer, the gate line on the array substrate to which the spacer position corresponds is removed. In this manner, there does not exist the problem that gate lines on the array substrate to which the spacer position corresponds have nonuniform thicknesses, thereby solving the problem in conventional display panels of gaps having different sizes after cell assembly of display panels because of nonuniform thicknesses of gate lines on the array substrate to which the spacer corresponds. This, in turn, avoids the problem of inhomogeneous color in the display. Meanwhile, the qualification rate of the obtained displays can be greatly improved, which reduces waste of the production materials, significantly reduces production costs, and improves production efficiency.

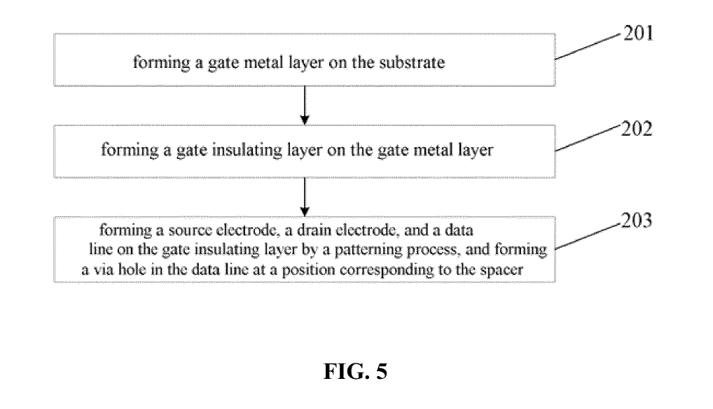

A method of producing an array substrate, according to an exemplary embodiment, is shown in FIG. 5. The method comprises the following steps:

Step 201 includes forming a gate metal layer on a substrate.

Step 202 includes forming a gate insulating layer on the gate metal layer.

Step 203 includes forming a source electrode, a drain electrode, and a data line on the gate insulating layer by a patterning process, and forming a via hole in the data line at a position corresponding to the spacer.

The same descriptions of the steps of the flow in the present exemplary embodiment are similar to the explanations provided in the above exemplary embodiment and will not be repeated here.

In the method of producing an array substrate, according to this exemplary embodiment, by forming a via hole in the data line on the array substrate at a position corresponding to the spacer, the data line on the array substrate to which the spacer position corresponds is removed. In this manner, there does not exist the problem that data lines on the array substrate to which the spacer position corresponds have nonuniform thicknesses, thereby solving the problem in conventional display panels of gaps having different sizes after cell assembly of display panels because of nonuniform thicknesses of data lines on the array substrate to which the spacer corresponds. This, in turn, avoids the problem of inhomogeneous color in the display. Meanwhile, the qualification rate of the obtained displays can be greatly improved, which reduces waste of the production materials, significantly reduces production costs, and improves production efficiency.

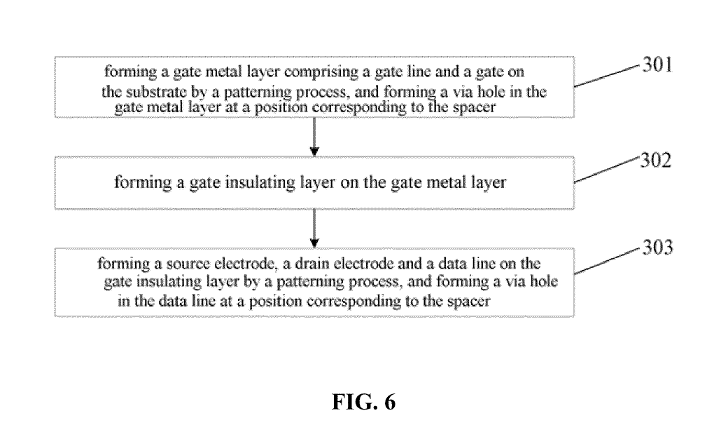

A method of producing an array substrate, according to an exemplary embodiment, is shown in FIG. 6. The method comprises the following steps:

Step 301 includes forming a gate metal layer comprising a gate line and a gate on a substrate by a patterning process, and forming a via hole in the gate metal layer at a position corresponding to the spacer.

Step 302 includes forming a gate insulating layer on the gate metal layer.

Step 303 includes forming a source electrode, a drain electrode, and a data line on the gate insulating layer by a patterning process, and forming a via hole in the data line at a position corresponding to the spacer.

The same descriptions of the steps of the flow in the present exemplary embodiment are similar to the explanations provided in the above exemplary embodiment, and will not be repeated here.

In the method of producing an array substrate, according to this exemplary embodiment, by forming a via hole in the gate line and the data line on the array substrate at a position corresponding to the spacer, the gate line and the data line on the array substrate to which the spacer position corresponds are removed. In this manner, there does not exist the problem that gate lines and data lines on the array substrate to which the spacer position corresponds have nonuniform thicknesses, thereby solving the problem in conventional display panels of gaps having different sizes after cell assembly of display panels because of nonuniform thicknesses of gate lines and data lines on the array substrate to which the spacer corresponds. This, in turn, avoids the problem of inhomogeneous color in the display. Meanwhile, the qualification rate of the obtained displays can be greatly improved, which reduces waste of the production materials, significantly reduces production costs, and improves production efficiency.

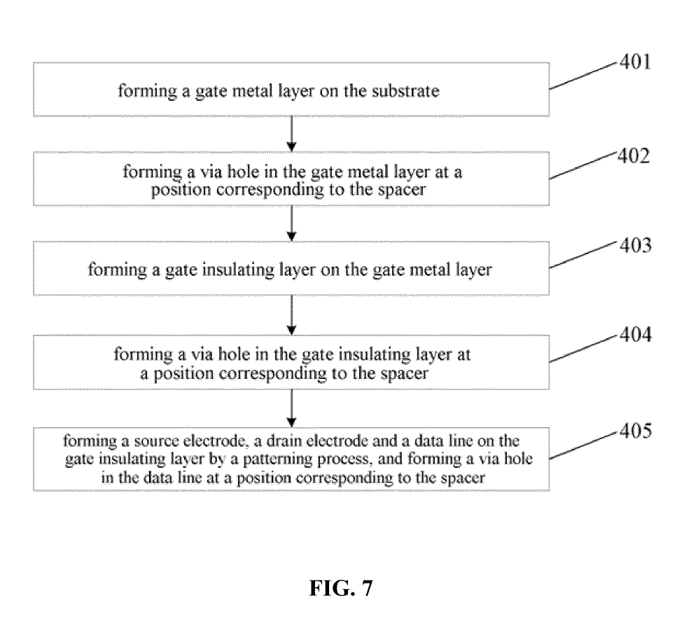

A method of producing an array substrate, according to an exemplary embodiment, is shown in FIG. 7. The method comprises the following steps:

Step 401 includes forming a gate metal layer on a substrate. Specifically, a gate metal layer comprising a gate line and a gate is formed on a substrate by a patterning process.

Step 402 includes forming a via hole in the gate metal layer at a position corresponding to the spacer.

Step 403 includes forming a gate insulating layer on the gate metal layer.

Step 404 includes forming a via hole in the gate insulating layer at a position corresponding to the spacer. The via hole in the gate insulating layer is connected to the via hole in the gate metal layer.

The step 403 of forming a gate insulating layer and the step 404 of forming a via hole in the gate insulating layer can be performed in any order.

The via hole in the step 402 can be formed simultaneously with the formation of the gate metal layer in the step 401 using the same process, which can also be formed simultaneously with the formation of the via hole in the gate insulating layer in the step 404. In practice, the specific operation order is determined by the formation of via holes in the gate metal layer and the gate insulating layer.

Step 405 includes forming a source electrode, a drain electrode, and a data line in the gate insulating layer by a patterning process, and forming a via hole in the data line at a position corresponding to the spacer.

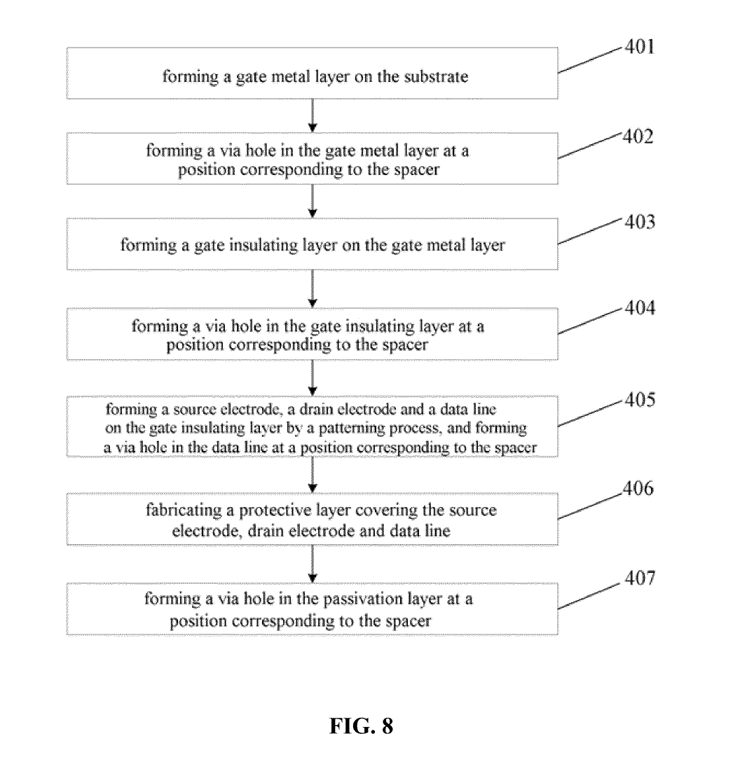

As shown in FIG. 8, a further exemplary embodiment includes the following additional steps, after the step 405:

Step 406 includes fabricating a protective layer covering the source electrode, drain electrode, and data line. Specifically, using a method similar to that used to produce the gate insulating layer and the active layer, the whole substrate is coated with a passivation layer having a thickness of from 1,000Å to 6,000Å, and the material thereof can be, for example, silicon nitride or transparent organic resin material.

Step 407 includes forming a via hole in the passivation layer at a position corresponding to the spacer. Specifically, said via hole can be formed by any suitable process, for example, etching.

The same descriptions of the steps of the flow in the present exemplary embodiment are similar to the explanations provided in the above exemplary embodiment, and will not be repeated here.

If the gate insulating layer is formed by a sputtering process using a sputtering device during production, due to the deficiencies possessed by the sputtering device, and if the array substrate where the spacer is located has the gate insulating layer, there will be the problem of inhomogeneous color in the display because gaps of different sizes will exist after cell assembly of display panels due to nonuniform thicknesses of the gate insulating layer. However, in accordance with this exemplary embodiment, the position in the gate insulating layer which corresponds to the spacer is provided with a via hole, which can effectively avoid the problem of inhomogeneous color in the display, greatly reduce production costs, and improve production efficiency.

In the method of producing an array substrate, according to this exemplary embodiment, by forming a via hole in the gate line on the array substrate at a position corresponding to the spacer, the gate line on the array substrate to which the spacer position corresponds is removed. In this manner, there does not exist the problem that gate lines on the array substrate to which the spacer position corresponds have nonuniform thicknesses, thereby solving the problem in conventional display panels of gaps having different sizes after cell assembly of display panels because of nonuniform thicknesses of gate lines on the array substrate to which the spacer corresponds. This, in turn, avoids the problem of inhomogeneous color in the display. Meanwhile, the qualification rate of the obtained displays can be greatly improved, which reduces waste of the production materials, significantly reduces production costs, and improves production efficiency.

Furthermore, forming a via hole in the gate insulating layer at a position corresponding to the spacer avoids the problem that the display panel has a nonuniform thickness because the gate insulating layer was formed using a sputtering device.

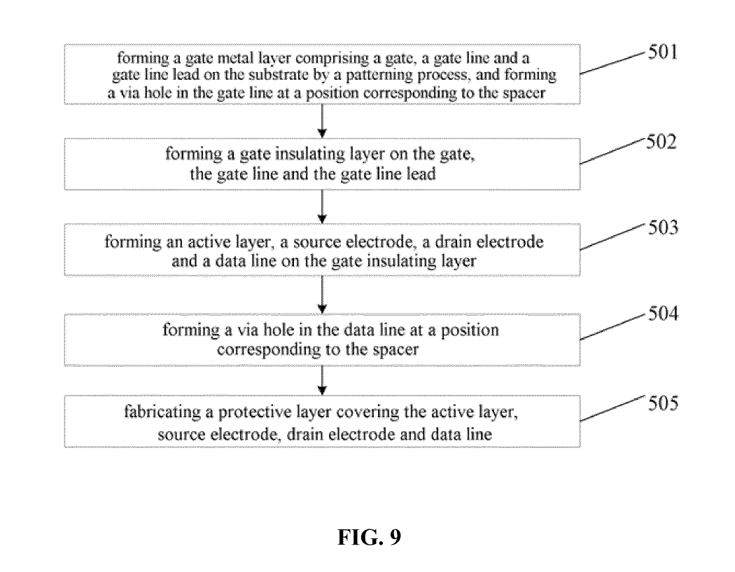

A method of producing an array substrate, according to an exemplary embodiment, is shown in FIG. 9. In this case, the gate line and the data line are both provided with a via hole at a position corresponding to the spacer. The method comprises the following steps:

Step 501 includes forming a gate metal layer comprising a gate, a gate line, and a gate line lead on a substrate by a patterning process, and forming a via hole in the gate line at a position corresponding to the spacer. Said via hole may be formed, for example, by an etching process using a mask plate. Specifically, a metal thin film layer having a thickness of from 1,000Å to 7,000Å is deposited on a substrate, such as a glass or quartz substrate, using a magnetron sputtering or a thermal evaporation method. Said metal thin film can employ any suitable material, such as molybdenum, aluminum, aluminum-nickel alloy, molybdenum-tungsten alloy, chromium, copper, etc., and can also employ a combined structure of the above thin film materials. Thereafter, said metal thin film is treated with a mask plate by means of a patterning process such as exposure, development, etching, and stripping to form a plurality of lateral gate lines and gates connected to the gate lines, as well as gate line leads between gate lines over a certain region of the substrate.

Step 502 includes forming a gate insulating layer over the gates, gate lines, and gate line leads. Specifically, a gate electrode insulating layer thin film having a thickness of from 1,000Å to 6,000Åcan be deposited on the substrate using a chemical vapor deposition method or a magnetron sputtering method. Said gate insulating layer thin film can employ any suitable material, such as nitrogen oxide, silicon oxide, silicon oxynitride, etc.

Step 503 includes forming a source electrode, a drain electrode, and a data line on the gate insulating layer. Specifically, a metal oxide semiconductor thin film can be deposited on the gate insulating layer using a chemical vapor deposition method, and then the metal oxide semiconductor thin film is treated by a patterning process to form an active layer, i.e., forming an active layer by performing exposure, development, and etching of the substrate using a common mask plate after it is coated with photoresist. Further, a metal thin film layer similar to the gate metal having a thickness of from 1,000Å to 7,000Å is deposited on the substrate using a method similar to that used to produce the gate lines. Said metal thin film layer is treated by a patterning process to form a source electrode, a drain electrode, and a data line over a certain region.

Step 504 includes forming a via hole in the data line at a position corresponding to the spacer. Said via hole can be formed, for example, by an etching process using a mask plate.

In an exemplary embodiment, the step 505 of forming the via hole in the data line and the step 504 of fowling the data line are performed simultaneously.

Step 505 includes forming a protective layer covering the active layer, the source electrode, the drain electrode, and the data line. Specifically, using a method similar to that used to produce the gate insulating layer and the active layer, the whole substrate is coated with a passivation layer having a thickness of from 1,000Å to 6,000Å, and the material thereof is, for example, silicon nitride or transparent organic resin material.

In the method of producing an array substrate, according to this exemplary embodiment, by forming a via hole in the gate line and the data line on the array substrate at a position corresponding to the spacer, the gate line and the data line on the array substrate to which the spacer position corresponds are removed. In this manner, there does not exist the problem that the gate lines and the data lines on the array substrate to which the spacer position corresponds have nonuniform thicknesses, thereby solving the problem in conventional display panels of gaps having different sizes after cell assembly of display panels because of nonuniform thicknesses of gate lines and data lines on the array substrate to which the spacer corresponds. This, in turn, avoids the problem of inhomogeneous color in the display. Meanwhile, the qualification rate of the obtained displays can be greatly improved, which reduces waste of the production materials, significantly reduces production costs, and improves production efficiency.

A display panel, according to an exemplary embodiment, comprises any of the exemplary array substrates disclosed or suggested herein. Said display panel may be a display panel of any product or component having a display function, such as a mobile phone, a tablet computer, a television, a notebook computer, a digital frame, a GPS navigator, etc.

In the display panel, according to this exemplary embodiment, by forming a via hole in the gate line and/or the data line on the array substrate at a position corresponding to the spacer, the gate line and/or the data line on the array substrate to which the spacer position corresponds is removed. In this manner, there does not exist the problem that gate lines and/or data lines on the array substrate to which the spacer position corresponds have nonuniform thicknesses, thereby solving the problem in conventional display panels of gaps having different sizes after cell assembly of display panels because of nonuniform thicknesses of gate lines and/or data lines on the array substrate to which the spacer corresponds. This, in turn, avoids the problem of inhomogeneous color in the display. Meanwhile, the qualification rate of the obtained displays can be greatly improved, which reduces waste of the production materials, significantly reduces production costs, and improves production efficiency.

Although the present disclosure has been described with reference to specific embodiments, it should be understood that the limitations of the described embodiments are provided merely for purpose of illustration and are not intended to limit the present invention and associated general inventive concepts. Instead, the scope of the present invention is defined by the appended claims, and all variations and equivalents that fall within the range of the claims are intended to be embraced therein. Thus, other embodiments than the specific exemplary ones described herein are equally possible within the scope of these appended claims.

1. An array substrate comprises a substrate, a gate line, a gate insulating layer, and a data line,
wherein at least one of said gate line and said data line is provided with a via hole at a position corresponding to a spacer.

2. The array substrate of claim 1, wherein said gate line and said gate insulating layer are provided with a via hole at a position corresponding to said spacer.

3. The array substrate of claim 1, said array substrate further comprising a passivation layer located on said substrate, said gate line, said gate insulating layer, and said data line,
wherein said passivation layer is provided with a via hole at a position corresponding to said spacer.

4. The array substrate of claim 1, wherein a position on the array substrate which corresponds with a position of said spacer comprises an active layer, a passivation layer, and an ITO pixel electrode layer.

5. The array substrate of claim 1, wherein a position on the array substrate which corresponds with a position of said spacer comprises a first ITO pixel electrode layer, an active layer, a passivation layer, and a second ITO pixel electrode layer.

6. A method of producing an array substrate, the method comprising:
forming a gate metal layer on a substrate;
forming a gate insulating layer on said gate metal layer; and
forming a source electrode, a drain electrode, and a data line on said gate insulating layer;
wherein a via hole is formed in at least one of said gate metal layer and said data line at a position corresponding to said spacer.

7. The method of claim 6, wherein said forming a gate metal layer on a substrate comprises:
forming a gate metal layer comprising a gate line and a gate on said substrate by a patterning process, and
forming a via hole in said gate line at a position corresponding to said spacer.

8. The method of claim 6, wherein said forming a gate metal layer on a substrate comprises:
forming a gate metal layer comprising a gate line and a gate on said substrate by a patterning process; and
after forming said gate insulating layer on said gate metal layer, forming a via hole penetrating said gate line and said gate insulating layer at a position corresponding to said spacer.

9. The method of claim 6, wherein said forming a source electrode, a drain electrode, and a data line on said gate insulating layer comprises:
forming a source electrode, a drain electrode, and a data line on said gate insulating layer by a patterning process, and
forming a via hole in said data line at a position corresponding to said spacer.

10. The method of claim 6, further comprising forming a via hole in said gate insulating layer at a position corresponding to said spacer.

11. The method of claim 6, further comprising forming a via hole in a passivation layer at a position corresponding to said spacer.

12. A display panel comprising an array substrate, said array substrate comprising a substrate, a gate line, a gate insulating layer, and a data line,
wherein at least one of said gate line and said data line is provided with a via hole at a position corresponding to a spacer.

13. The display panel of claim 12, wherein said gate line and said gate insulating layer are provided with a via hole at a position corresponding to said spacer.

14. The display panel of claim 12, wherein said array substrate further comprises a passivation layer located on said substrate, said gate line, said gate insulating layer, and said data line, and
wherein said passivation layer is provided with a via hole at a position corresponding to said spacer.

15. The display panel of claim 12, wherein a position on the array substrate which corresponds with a position of said spacer comprises an active layer, a passivation layer, and an ITO pixel electrode layer.

16. The display panel of claim 12, wherein a position on the array substrate which corresponds with a position of said spacer comprises a first ITO pixel electrode layer, an active layer, a passivation layer, and a second ITO pixel electrode layer.
